(19) United States
(12) Patent Application Publication
(10) Pub. No.: US 2026/0173479 A1
(43) Pub. Date: Jun. 18, 2026

(54) TRANSISTORS WITH MULTILEVEL FIELD PLATES

(71) Applicant: NXP USA, Inc., AUSTIN, TX (US)

(72) Inventors: Humayun Kabir, Gilbert, AZ (US); Bernhard Grote, Phoenix, AZ (US); Ibrahim Khalil, Phoenix, AZ (US)

(21) Appl. No.: 18/985,582

(22) Filed: Dec. 18, 2024

(51) Int. Cl. H10D 64/00; H10D 30/01; H10D 30/47; H10D 62/85; H10D 64/01

(52) U.S. Cl. CPC H10D 64/112; H10D 30/015; H10D 30/471; H10D 62/8503; H10D 64/01

(57) ABSTRACT

Greater flexibility in the design of transistors (e.g., heterostructure field effect transistors) which utilize field plates over the transistor channel can be realized using a multilevel field plate. A first field plate segment formed is disposed above the channel region between the gate electrode and the second current terminal (e.g., the drain) that is separated from the gate electrode by a first volume of dielectric material. A second field plate segment is formed above the channel region and separated from the first field plate segment and the gate electrode by a second volume of dielectric material. The first field plate segment and the second field plate segment are connected to the first current terminal (e.g., the source terminal of the transistor). The second field plate segment extends above the channel region from the first end of the channel region to a second location above the channel region between the gate electrode and the second current terminal.

### TECHNICAL FIELD

Embodiments of the subject matter described herein relate generally to semiconductor devices with conductive elements and methods for fabricating such devices.

### BACKGROUND

Semiconductor devices find application in a wide variety of electronic components and systems. High power, high frequency transistors find application in radio frequency (RF) systems and power electronics systems. Gallium nitride (GaN) device technology is particularly suited for these RF power and power electronics applications due to its superior electronic and thermal characteristics. In particular, the high electron velocity and high breakdown field strength of GaN make devices fabricated from this material ideal for RF power amplifiers and high-power switching applications. Field plates are used to reduce gate-drain feedback capacitance and to increase device breakdown voltage in such transistors. Accordingly, there is a need for semiconductor and, in particular, GaN transistors with field plates.

### SUMMARY

In an example embodiment a semiconductor device includes a channel region that extends from a first current terminal connected to a first end of the channel region to a second current terminal connected to a second end of the channel region. The device also includes a gate electrode disposed the channel region that is electrically coupled to a top surface of the channel region, and a multilevel field plate.

The multilevel field plate includes a first field plate segment disposed above the channel region between the gate electrode and the second current terminal that is separated from the gate electrode by a first volume of dielectric material. The multilevel field plate also includes a second field plate segment disposed above the channel region and separated from the first field plate segment and the gate electrode by a second volume of dielectric material. The first field plate segment and the second field plate segment are connected to the first current terminal. The second field plate segment extends above the channel region from the first end of the channel region to a second location above the channel region between the gate electrode and the second current terminal.

In another example embodiment a method of fabricating a semiconductor device includes providing a substrate with a channel region that extends from a first current terminal connected to a first end of the channel region to a second current terminal connected to a second end of the channel region. A gate electrode is formed above the channel region that is electrically coupled to a top surface of the channel region and a multilevel field plate field plate is formed.

Forming the multilevel field plate includes forming a first field plate segment disposed above the channel region between the gate electrode and the second current terminal that is separated from the gate electrode by a first volume of dielectric material. Forming the multilevel field plate also includes forming a second field plate segment disposed above the channel region and separated from the first field plate segment and the gate electrode by a second volume of dielectric material. The first field plate segment and the second field plate segment are connected to the first current terminal. The second field plate segment extends above the channel region from the first end of the channel region to a second location above the channel region between the gate electrode and the second current terminal.

### BRIEF DESCRIPTION OF THE DRAWINGS

The present disclosure is illustrated by way of examples, embodiments and the like and is not limited by the accompanying figures, in which like reference numbers indicate similar elements. The figures along with the detailed description are incorporated and form part of the specification and serve to further illustrate examples, embodiments and the like, and explain various principles and advantages, in accordance with the present disclosure, wherein:

FIG. 1 is a schematic cross-sectional view of an example transistor according to one or more embodiments.

FIG. 2 is a schematic overhead plan of view of the transistor of FIG. 1.

FIG. 3 is a perspective view of the transistor of FIG. 1 and FIG. 2

### DETAILED DESCRIPTION

The following detailed description provides examples for the purposes of understanding and is not intended to limit embodiments of this disclosure and uses of the same. It will be understood that numerous related techniques and devices and variations of the same are disclosed for ease of understanding and that these techniques and variations can be combined in numerous ways. It will also be understood that the Applicant has chosen to claim particular combinations of the disclosed techniques and/or devices and that not every combination disclosed is claimed. Furthermore, there is no intention to be bound by any expressed or implied theory presented in the preceding technical field, background, or the detailed description.

For simplicity and clarity of illustration, elements in the drawings are not necessarily drawn to scale. For example, the dimensions of some of the elements or regions in the figures may be exaggerated relative to other elements or regions to help improve understanding of embodiments of the invention. Directional references such as “top,” “bottom,” “left,” “right,” “above,” “below,” and so forth, unless otherwise stated, are not intended to require any preferred orientation, and are made with reference to the orientation of the corresponding figure or figures for purposes of illustration. In addition, the Figures and Detailed Description may omit well-known and conventional features for clarity.

Field plates, and particularly field plates coupled to the source terminal of transistors (which is often grounded or otherwise coupled to reference voltage node) have become increasingly common in high performance transistors as a way to improve high voltage performance characteristics such as breakdown voltage without enlarging the footprint of the transistor by reducing the gate-to-drain (C_{GD}) capacitance and increasing gain. The length of a source-coupled field plate is a design variable that directly impacts the gate-drain coupling, device breakdown, and transition frequency (fₜ). However, while source-coupled field plates have been employed successfully, they can also introduce added gate-to-source (C_{GS}) and drain-to source capacitance (C_{DS}). Thus, designing a transistor with one or more field plates typically requires various trade-offs between reduced C_{GD} and increasing other capacitances in the device. Compared to a single level field, a dual level field plate according to one or more embodiments disclosed herein is expected to provide better protection against gate-drain coupling resulting in reduced C_{GD} and thus improved gain than a single layer field plate. Along these lines, transistors according to one or more embodiments disclosed herein include a multi-level field plate which can provide additional design flexibility, as described further below.

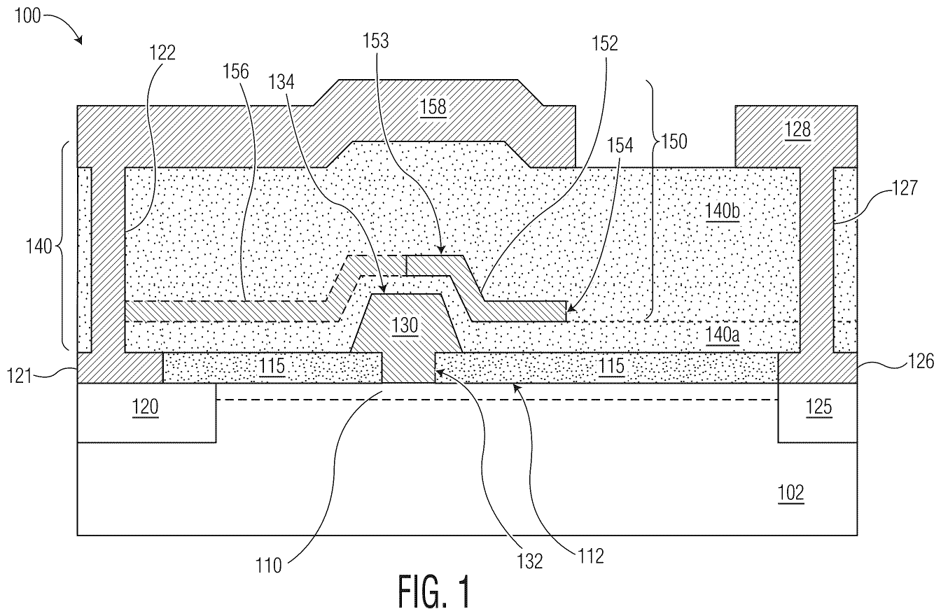

FIG. 1 is a schematic cross-sectional view of example transistor according to one or more embodiments. The transistor 100 is formed on a semiconductor substrate 102 and has a channel region 110 near a top surface 112 of the substrate 102. The transistor 100 includes a first current terminal 120 electrically coupled to a first end of the channel region 110 and a second current terminal 125 electrically coupled to a second end of the channel region 110 opposite the first current terminal 120. It will be understood that features of the transistor 100 above (and features of other example transistors herein) may be compatible with various transistor technologies. For instance, the transistor 100 and/or any other example transistor according to embodiments herein may be a metal-MOSFET or MISFET fabricated on a silicon substrate or any other suitable semiconductor substrate. For instance, in one or more embodiments, a transistor such as the transistor 100 is a III-V compound semiconductor-based high-electron-mobility transistor (“HEMT”), otherwise known as a heterostructure field effect transistor (“HFET”). In such embodiments the effective semiconductor channel may be a 2D electron gas (“2DEG”) formed at a semiconductor heterojunction disposed with the channel region 110 according to known techniques.

A passivation material 115 (e.g., a dielectric) is disposed on the top surface 112 overlying the channel region 110. The first current terminal 120 and the second current terminal 125 may be formed by any suitable methods. For example, they may be appropriately doped regions within the semiconductor substrate 102, or as metallic contacts deposited within recesses in the substrate 102 or on the surface of the substrate 102. The current terminals 120,125 can be overlaid by respective metallic contacts 121, 126 (hereinafter a source contact 121 and a drain contact 126) and respective vias 122, 127 that pass through one or more dielectric layers to make electrical contact to the current terminals. As shown, the current terminals 120, 125 can be connected to larger metallic contact pads disposed above the dielectric material 140, a drain contact pad 128 and a source contact pad (formed by a field plate segment 158 described further below in connection with the field plate 150).

The passivation material 115 is overlaid as shown by additional dielectric material 140 (shown as two volumes of dielectric material 140a, 140b). The volumes of dielectric material 140a, 140b can be formed from different materials or formed from the same material. A conductive first electrode (hereinafter a control electrode or gate 130) contacts the channel region 110 through an aperture in the passivation material 115 and the dielectric material 140. As shown, the gate 130 has a first end 132 that contacts the channel region 110 within the aperture and optionally has a second end 134 that overhangs the passivation material 115. Although portions of the gate 130 are depicted as having vertical sidewalls and other portions are depicted with slanted sidewalls, it will be understood that the gate 130 may have any suitable geometry. For instance, the first end 132 of the control electrode may have sidewalls that are curved or slanted. Similarly, the second end 134 of the gate 130 may have sidewalls that are curved or slanted and the top surface (farthest from the channel region 110) my have any suitable geometry. The gate 130 is disposed in between the first current terminal 120 and the second current terminal 125 along the length of the channel region 110. It will be appreciated that the volumes of dielectric material 140a, 140b are shown as nonlimiting examples for purposes of illustration and that embodiments are not limited to any particular number or arrangement of dielectric layers.

It will be appreciated that the first current terminal 120 may be operated, for example, as a source terminal of the transistor 100 and the second current terminal 125 may be operated, for example, as a drain terminal of the transistor 100. It should also be understood that the gate 130 is suitable for use as a control electrode of the transistor 100 such that, when a suitable bias voltage is applied to the gate 130, the channel region 110 is configured to provide an electrically conductive path between the first current terminal 120 and the second current terminal 125. In the example of FIG. 1 the gate 130 is shown in direct contact with the top surface 112 above the channel region 110 (i.e., the gate 130 forms a Schottky contact at the top surface 112 to the semiconductor material that forms the channel region 110).

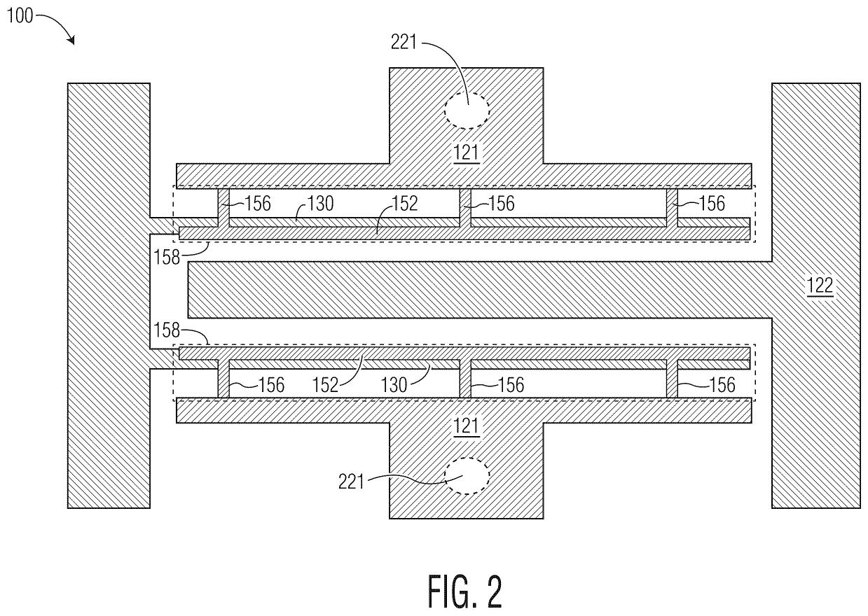

As shown in FIG. 1, the transistor 100 also includes a multilevel field plate electrode (hereinafter a field plate 150). The field plate 150 includes a first field plate segment 152 and a second field plate segment 158 formed in at least two separate metal layers. The first field plate segment 152 has a first end 153 disposed above the gate 130 and a second end 154 disposed above the channel region 110 between the gate 130 and the second current terminal 125 and the channel region. The first end 153 of the first field plate segment 152 is electrically connected to the first current terminal 120 via one or more electrical interconnects 156 (described in greater detail below with reference to FIG. 2). It will be understood that the first field plate segment 152 is shown as an example and that such a field plate field plate segment can have any suitable geometry.

The second field plate segment 158 is formed above the dielectric material 140 which separates the second field plate segment 158 from the first field plate segment 152. The second field plate segment 158 is also electrically connected to the first current terminal 120 by way of the via 122 and the contact 121. The second field plate segment 158 of the field plate 150 overhangs the channel region 110 and extends over the first field plate segment 152. In one or more embodiments, the second field plate segment 158 forms all or part of a metal layer that provides access to the current terminal 120 for connecting the transistor 100 to a leadframe within a device package (e.g., via wire bonds) or other electronic devices.

It will be understood that, when the first current terminal 120 is operated as a source terminal of the transistor 100, the field plate 150 may be configured to operate as source-coupled field plate. The field plate 150 may be coupled to the current terminal 120 (operable as the source of the transistor 100) via one or more additional electrically conductive interconnects which are not pictured. In one or more embodiments, the field plate 150 may extend in one or more locations to contact the current terminal 120 directly (i.e., in the cross-sectional plane pictured or in or more other cross-sectional planes of the transistor 100). In the transistor 100, the conductance of the channel region 110 during operation of the transistor 100 will be influenced by the electrical potential of the gate 130 and the field plate 150. It will be appreciated that the field plate 150 is capacitively coupled to the channel region 110, primarily across the passivation material 115. Meanwhile the field plate 150 is also capacitively coupled to the gate 130, primarily across the dielectric material 140.

Generally, a field plate, when coupled to a source terminal of a transistor may be used to reduce gate-to-drain feedback capacitance (“C_{GD}”) in transistors such as the transistor 100 when compared to otherwise similar transistors lacking such a field plate. However, the addition of a source-coupled field plate spaced apart from a control electrode such as the gate 130 will also tend to introduce additional capacitance between the gate and the source (“C_{GS}”). It will be understood In embodiments herein, multiple dielectric layers may be used to realize a desired value for C_{GD} while mitigating the additional C_{GS} introduced by the field plate. In addition, the shape of a field plate electrode, particularly near a channel region (e.g., the first field plate segment 152 of the field plate 150) can influence the electric field distribution in the channel region which can in turn affect performance characteristics of the transistor such as gain and breakdown voltage, as nonlimiting examples.

The multilevel configuration of the field plate 150 can provide significantly larger reduction of C_{GD} when compared with conventional approaches featuring only a single field plate field plate segment such as the first field plate segment 152 of the field plate 150. Although a multilevel field plate such as the field plate 150 may introduce additional capacitance between the drain and source (C_{DS}) of a transistor (e.g., between the current terminal 120 operated as the source of the transistor 100 and the current terminal 125 operated as the drain of the transistor 100), this can be a worthwhile tradeoff in certain frequences in order to realize improved gain. For example, transistors according to embodiments herein can exhibit improved gain without undesirable performance reductions at frequencies below 10 GHz.

It will be understood that, in or more embodiments, various dielectric layers and electrodes described herein may be jointly configured and arranged to achieve certain performance metrics or other device characteristics and that such metrics may be defined in absolute or relative terms. Non-limiting examples include absolute capacitance values such as C_{GD}, C_{GS,} and/or C_{DS} as well as ratios between such capacitance values. These and other capacitance values may be expressed in term of absolute capacitances or capacitances per unit of cross-sectional area or per unit of length.

In the transistor 100 and related transistors according to embodiments described herein, the use of multiple dielectric layers configured as described may confer certain advantages. Specifically, the relative dielectric constants and thicknesses of each of these materials may be chosen to achieve desired performance characteristics and to facilitate various fabrication procedures in embodiments herein. In one or more embodiments, the passivation material 115 is a silicon oxide or an aluminum oxide. In one or more embodiments, the volume of dielectric material 140a is a nitride material (e.g., AlN or SiN), and the volume of dielectric material layer 140b is also a nitride. For instance, in the example of FIG. 1, the relative thicknesses and dielectric constants of the passivation material 115, and the dielectric material 140 (which in one or more embodiments includes two or more volumes) will tend to determine the effect of the field plate 150 (operating as a source-coupled field plate) on the channel region 110 and C_{GD} of the transistor 100 (i.e., the capacitance between the gate 130 and the second current terminal 125). Meanwhile, the dielectric constants and thicknesses of the volumes of dielectric material 140a, 140b, will largely determine the additional C_{GS} penalty. Thus, a material with a relatively high dielectric constant may be chosen for the passivation material 115 to maximize the influence of the field plate 150 on the channel region 110.

In one or more embodiments, the passivation material 115 is an aluminum oxide with a thickness in a range between 20 and 5,000 Ångströms. In or more embodiments the passivation material 115 has a thickness in a range between 50 and 1000 Ångströms. In one or more embodiments, the dielectric material layer 140a is a silicon nitride with a thickness in a range between 100 and 2000 Ångströms, although other ranges may be used in one or more other embodiments. In one or more embodiments, the volume of dielectric material 140b is a silicon oxide or silicon nitride material with a thickness in a range between 20 and 10,000 Ångströms.

Although the thickness ranges above are given as examples, it will be appreciated that other ranges are suitable for use in one or more embodiments. It will be further understood that the choices of materials and thicknesses for various dielectrics may be expressed in terms of an equivalent oxide thickness (“EOT,” i.e., the thickness of SiO₂ required to produce the same capacitance in a capacitor structure when a different dielectric is used). For instance, a layer of SiO₂ with a relative dielectric constant of 3.8 may be used as a reference. As an illustration, a 10 nm-thick layer of SiO₂ may be said to have an EOT of 10 nm while a 10 nm-thick layer of another dielectric (e.g., an aluminum oxide material) with a relative dielectric constant of 9.5 would have an EOT of only 4 nm as a result of the higher electric permeability of the alternative material.

In one or more embodiments, a transistor such as the transistor 100 is a gallium-nitride (GaN) based HEMT. In one or more such embodiments, a 2DEG is formed at an interface between a GaN layer and an aluminum doped layer with a stochiometric composition described by the chemical formula AlₓGa₁₋ₓN or AlₓIn₍₁₋ₓ₎N where x is between zero and one. It will be understood that, in such embodiments, the effective channel may be buried within the channel region 110 and may not extend to the top surface 112 of the channel region 110. In one or more embodiments, the passivation material 115 may be a material that provides surface passivation for the channel region 110 (e.g., by mitigating the influence of unwanted available electron energy states arising from dangling bonds at the top surface 112 of the substrate 102).

FIG. 2 is an overhead plan view of the transistor 100. Transistors such as the transistor 100 and related transistors can be formed using multiple interdigitated “fingers” corresponding to source (e.g., the current terminal 120), drain (e.g., the current terminal 125, and channel regions (e.g., one or more channel regions 110) which are controlled via gate electrodes (gate “fingers”). For simplicity the transistor 100 is depicted as a unit cell that includes a single drain finger (formed, for example, by a drain contact 126) Which is flanked by two source fingers (formed, for example by two source contacts 121). The source contacts 121 can be electrically connected to each other by way of vias 221 that couple each source contact 121 to a reference voltage node such as a ground plane or other electrically conductive structure (no shown) formed beneath the channel region 110 (e.g., on the back side of the substrate 102 opposite the top surface 112). A gate finger (e.g., a gate 130) is disposed between the drain contact 126 and each source contact 121. A first field plate segment 152 partially overlies each gate 130 (e.g., as shown in FIG. 1).

Each first field plate segment 152 is connected to a corresponding source contact 121 via interconnects 156 disposed intermittently along the length of each first field plate segment 152. Each first field plate segment 152 and each source contact 151 is overlied by a respective second field plate segment 158 (indicated by an unfilled dashed box) which is electrically connected to a respective source contact 121 as shown in FIG. 1.

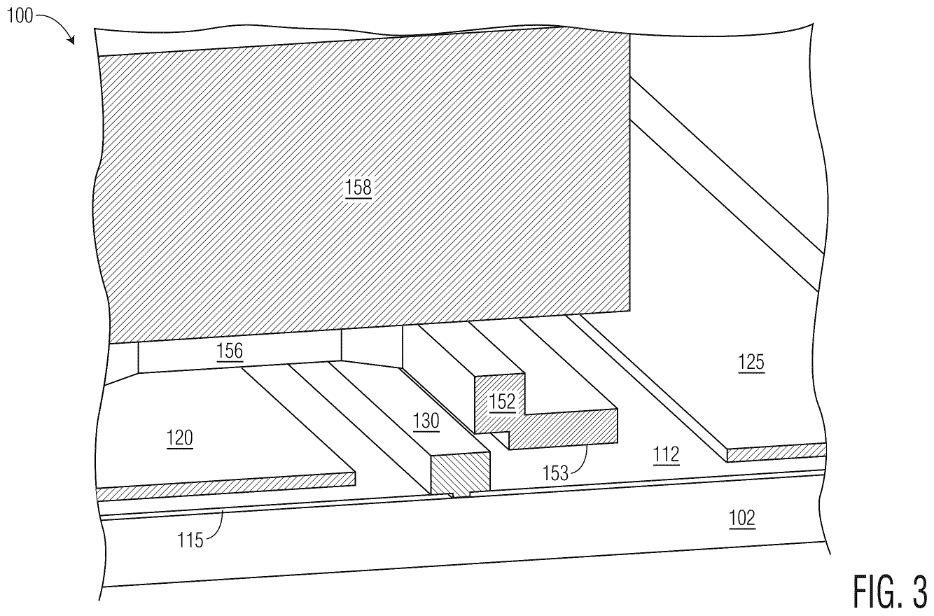

FIG. 3 is a cross-sectional perspective view showing elements of the transistor 100 in greater detail. The passivation material 115 and dielectric material 140 are removed to clearly show the source (i.e., the first current terminal 120 of FIG. 1), drain (i.e., the second current terminal 125 of FIG. 1), a gate 130, a first field plate segment 152 (with an interconnect 156), and a second field plate segment 158.

### EXAMPLES

Features of embodiments may be understood by way of one or more of the following examples:

Example 1: A semiconductor device or method of fabricating a semiconductor device that includes a channel region that extends from a first current terminal connected to a first end of the channel region to a second current terminal connected to a second end of the channel region. A gate electrode is formed above the channel region and electrically coupled to a top surface of the channel region. A multilevel field plate formed above the channel region includes: a first field plate segment formed above the channel region between the gate electrode and the second current terminal that is separated from the gate electrode by a first volume of dielectric material. The multilevel field plate also includes a second field plate segment formed above the channel region and separated from the first field plate segment and the gate electrode by a second volume of dielectric material. The first field plate segment and the second field plate segment are connected to the first current terminal. The the second field plate segment extends above the channel region from the first end of the channel region to a second location above the channel region between the gate electrode and the second current terminal.

Example 2: The device or method of Example 1, where the second field plate segment overhangs an entirety of the first field plate segment.

Example 3: The device or method of Example 1 or Example 2, where the first field plate segment has a first end that extends over a portion of the gate electrode and a second end that extends over a portion of the channel region disposed between the gate electrode and the second current terminal.

Example 4: The device or method of any one of Examples 1-3, where the second end of the first field plate segment is separated from the top surface of the channel region by at least part of the first volume of dielectric material.

Example 5: The device or method of any one of Examples 1-4, further includes a passivation material disposed directly on the top surface of the channel region; where the second end of the first field plate segment is disposed directly on the passivation material.

Example 6: The device or method of any one of Examples 1-5 where the semiconductor device is a heterostructure transistor formed from a semiconductor heterostructure configured to form a two-dimensional charge gas (2DCG) at a semiconductor interface within the channel region.

Example 7: The device or method of any one of Examples 1-6 where the first current terminal is the source terminal of a transistor, and the second current terminal is a drain terminal of the transistor.

Example 8: The device or method of any one of Examples 1-7 where an edge of the second end of the first field plate segment that is distal to the gate electrode is disposed at least one micron away from an edge of the gate electrode that is proximal to the second end of the first field plate segment.

Example 9: The device of method of any of Examples 1-8 where the second field plate segment overhangs at least an entirety of the channel region between the first current terminal and the first field plate segment.

Example 10: The device or method of any of Examples 1-9 where an equivalent oxide thickness between the second end of the first field plate segment and the channel region is less than an equivalent oxide thickness between the second field plate segment and the channel region.

Example 11: The device or method of any of Examples 1-10 where the first field plate segment is formed from a metal.

Example 12: The device or method of any of Examples 1-11 where second field plate segment is formed from a metal.

The preceding detailed description and Figures referenced therein are examples. They are illustrative in nature and are not intended to limit the embodiments of the Disclosure and uses of such embodiments. It should therefore be understood that embodiments of this Disclosure are not limited in their application to the details of construction and the arrangement of components set forth in the preceding Description or illustrated in the accompanying Figures.

The connecting lines shown in the various figures contained herein are intended to represent exemplary functional relationships and/or physical couplings between the various elements. It should be noted that many alternative or additional functional relationships or physical connections may be present in one or more embodiments of the Disclosure.

As used herein, the word “exemplary” means “serving as an example, instance, or illustration.” Any implementation described herein as exemplary is not necessarily to be construed as preferred or advantageous over other implementations. Furthermore, there is no intention to be bound by any expressed or implied theory presented in the preceding technical field, background, or detailed description. It is to be understood that other phraseology and terminology used herein is for the purpose of description and should not be regarded as limiting.

The terms “comprise,” “include,” “have” and any variations thereof, are intended to cover non-exclusive inclusions, such that a process, method, article, or apparatus that comprises a list of elements is not necessarily limited to those elements but may include other elements not expressly listed or inherent to such process, method, article, or apparatus. Herein, “A, B, and/or C” is defined as “A or B or C” or any combination of A, B, or C.

As used herein, unless expressly stated otherwise, “connected” means that one element is directly joined to (or directly communicates with) another element in an electrical or non-electrical manner, and not necessarily mechanically. Likewise, unless expressly stated otherwise, “coupled” means that one element is directly or indirectly joined to (or directly or indirectly communicates with) another element in an electrical or non-electrical manner, and not necessarily mechanically. Thus, although the schematic illustrations of the figures may depict exemplary arrangements of elements, additional intervening elements, devices, features, or components may be present in one or more embodiments of the depicted subject matter.

The terms “first,” “second” and other such numerical terms referring to structures do not imply a sequence or order unless clearly indicated by the context. Thus, the terms “first,” “second,” “third,” “fourth” and the like in the description and the claims, if any, may be used for distinguishing between similar elements and not necessarily for describing a particular sequential or chronological order. It is to be understood that numerical terms used herein are interchangeable under appropriate circumstances such that the embodiments of the invention described herein are, for example, capable of operation in sequences other than those illustrated or otherwise described herein.

As used herein the terms “approximate,” “approximately,” “substantial” and “substantially” mean sufficient to accomplish the stated purpose in a practical manner and that minor imperfections, if any, are not significant for the stated purpose. Along these lines, when used with references to measurable quantities including, but not limited to, dimensions, these terms mean that the quantities are equal to the values stated subject to accepted tolerances of any methods or apparatus chosen to fabricate the described structures or measure the quantities or dimensions described.

While at least one exemplary embodiment has been presented in the foregoing detailed description, it should be appreciated that a vast number of variations exist. It should also be appreciated that exemplary embodiments described herein are not intended to limit the scope, applicability, or configuration of the claimed subject matter in any way. Rather, the foregoing detailed description will provide those skilled in the art with a convenient road map for implementing the described embodiment or embodiments. It should be understood that various changes can be made in the function and arrangement of elements without departing from the scope defined by the claims, which includes known equivalents and foreseeable equivalents at the time of filing this patent application.

What is claimed is:

1. A semiconductor device comprising:
a channel region that extends from a first current terminal connected to a first end of the channel region to a second current terminal connected to a second end of the channel region;
a gate electrode disposed above the channel region that is electrically coupled to a top surface of the channel region; and
a multilevel field plate that comprises:
a first field plate segment disposed above the channel region between the gate electrode and the second current terminal that is separated from the gate electrode by a first volume of dielectric material;
a second field plate segment disposed above the channel region and separated from the first field plate segment and the gate electrode by a second volume of dielectric material;
wherein the first field plate segment and the second field plate segment are connected to the first current terminal;
wherein the second field plate segment extends above the channel region from the first end of the channel region to a second location above the channel region between the gate electrode and the second current terminal.

2. The semiconductor device of claim 1, wherein the second field plate segment overhangs an entirety of the first field plate segment.

3. The semiconductor device of claim 2, wherein the second field plate segment overhangs at least an entirety of the channel region between the first current terminal and the first field plate segment.

4. The semiconductor device of claim 1, wherein the first field plate segment has a first end that extends over a portion of the gate electrode and a second end that extends over a portion of the channel region disposed between the gate electrode and the second current terminal.

5. The semiconductor device of claim 4, an equivalent oxide thickness between the second end of the first field plate segment and the channel region is less than an equivalent oxide thickness between the second field plate segment and the channel region.

6. The semiconductor device of claim 5, wherein the second end of the first field plate segment is separated from the top surface of the channel region by at least part of the first volume of dielectric material.

7. The semiconductor device of claim 5, further comprising a passivation material disposed directly on the top surface of the channel region;
wherein the second end of the first field plate segment is disposed directly on the passivation material.

8. The semiconductor device of claim 1, wherein an edge of the second end of the first field plate segment that is distal to the gate electrode is disposed at least one micron away from an edge of the gate electrode that is proximal to the second end of the first field plate segment.

9. The semiconductor device of claim 1, wherein the semiconductor device is a heterostructure transistor formed from a semiconductor heterostructure configured to form a two-dimensional charge gas (2DCG) at a semiconductor interface within the channel region.

10. The semiconductor device of claim 9, wherein channel region is formed from gallium nitride (GaN).

11. The semiconductor device of claim 10
wherein the channel has a channel length defined by a distance between the first current terminal and the second terminal and a channel width that in a direction perpendicular to the channel length and parallel to the top surface of the channel region. The semiconductor device of claim 1 wherein the first field plate segment and the second field plate segment are formed from metal.

13. The semiconductor device of claim 1 where the first current terminal is coupled to a reference voltage node.

14. A method of fabricating a semiconductor device, the method comprising:
providing a semiconductor substrate having a channel region that extends from a first current terminal connected to a first end of the channel region to a second current terminal connected to a second end of the channel region;
forming a gate electrode disposed the channel region that is electrically coupled to a top surface of the channel region; and
forming a multilevel field plate by:
forming a first field plate segment disposed above the channel region between the gate electrode and the second current terminal that is separated from the gate electrode by a first volume of dielectric material;
forming a second field plate segment disposed above the channel region and separated from the first field plate segment and the gate electrode by a second volume of dielectric material;
wherein the first field plate segment and the second field plate segment are connected to the first current terminal;
wherein the second field plate segment extends above the channel region from the first end of the channel region to a second location above the channel region between the gate electrode and the second current terminal.

15. The method of claim 14, wherein the second field plate segment overhangs an entirety of the first field plate segment.

16. The method of claim 14, wherein the first field plate segment has a first end that extends over a portion of the gate electrode and a second end that extends over a portion of the channel region disposed between the gate electrode and the second current terminal.

17. The method of claim 16, wherein the second end of the first field plate segment is separated from the top surface of the channel region by at least part of the first volume of dielectric material.

18. The method of claim 16,
wherein a passivation material disposed directly on the top surface of the channel region;
wherein the second end of the first field plate segment is disposed directly on the passivation material.

19. The semiconductor device of claim 16 where the semiconductor device is a heterostructure transistor formed from a semiconductor heterostructure configured to form a two-dimensional charge gas (2DCG) at a semiconductor interface within the channel region.

20. The method of claim 14, wherein the first current terminal is coupled to a reference voltage node.
